(19) United States
(12) Patent Application Publication
(10) Pub. No.: US 2025/0212636 A1
(43) Pub. Date: Jun. 26, 2025

(54) SEMICONDUCTOR DEVICE, DISPLAY DEVICE, PHOTOELECTRIC CONVERSION DEVICE, AND ELECTRONIC DEVICE

(71) Applicant: CANON KABUSHIKI KAISHA, Tokyo (JP)

(72) Inventor: KAZUYA NOTSU, Kanagawa (JP)

(21) Appl. No.: 18/973,197

(22) Filed: Dec. 9, 2024

(30) Foreign Application Priority Data
Dec. 21, 2023 (JP) 2023-215504

(51) Int. Cl. H10K 59/131; H10K 59/129; H10K 59/88

(52) U.S. Cl. CPC H10K 59/131; H10K 59/129; H10K 59/88

(57) ABSTRACT

A semiconductor device according to the present invention includes: a semiconductor substrate; and a semiconductor chip electrically connected to the semiconductor substrate via a plurality of terminals, wherein the semiconductor substrate includes an effective element area and a peripheral area surrounding the effective element area, the peripheral area is provided with an electrode portion to which the semiconductor chip is electrically connected, the semiconductor chip is provided with a plurality of rows of terminal groups disposed along a first direction, and W1>W2 is satisfied, where W1 is a distance from an end of the semiconductor chip on a side closest to the effective element area to the terminal group, and W2 is a distance from an end of the semiconductor chip on a side farthest from the effective element area to the terminal group.

### BACKGROUND OF THE INVENTION

### Field of the Invention

The present invention relates to a semiconductor device, a display device, a photoelectric conversion device, and an electronic device.

### Description of the Related Art

In electronic devices, miniaturization, weight reduction, and high performance are required, and the number of external output terminals is rapidly increasing. With respect to the increase in the number of external output terminals, in the conventional wire bonding connection, there is a limit to narrowing the pitch of the connection terminals, and the electronic devices become large. Therefore, a technique of flip-chip mounting semiconductor chips has attracted attention.

In the flip-chip mounting, since the bonding pads miniaturized by the semiconductor process can be connected to each other via a connection portion such as a bump, it is possible to significantly narrow the pitch of the external output terminals as compared with the conventional wire bonding connection.

Examples of a bonding method of flip-chip mounting include ultrasonic bonding and solder bonding. In the manufacture of a display device such as an organic EL, a bonding method using an anisotropic conductive film (ACF) that can be bonded at a low temperature is generally used in order to suppress deterioration of an element due to heat in a bonding step.

JP 2016-127259 A and JP 2005-26682 A propose flip-chip mounting by ACF bonding. In addition, arrangement of electrodes and bumps and dummy bumps are also described. In the technique described in JP 2016-127259 A, dummy bumps are disposed between a first bump area and a second bump area divided on both sides of a chip, and the bumps are uniformly disposed on the chip, thereby reducing warpage of the chip at the time of flip-chip mounting and reducing electrical contact failure. In the technique described in JP 2005-26682 A, since the stress at the time of crimping is concentrated on the four corners of a chip, dummy bumps are disposed at the four corners of the chip to reduce the breakage of electrical connection.

However, JP 2016-127259 A and JP 2005-26682 A do not refer to the wiring of a semiconductor substrate, and when the electrode of the semiconductor chip is disposed on the side close to the effective pixel area of the semiconductor substrate, wiring routing becomes complicated. Therefore, it is necessary to move the semiconductor chip away from the effective pixel area, and there is a problem in that the size of the semiconductor substrate increases. In particular, in a case where this technology is utilized for a display device or an imaging apparatus, since the number of output terminals of the semiconductor chip increases and the wiring from the semiconductor chip to the effective pixel becomes dense, it is necessary to take a large area for routing the wiring, and the substrate size becomes larger.

### SUMMARY OF THE INVENTION

The present invention has been made in view of the above problems, and provides a technique advantageous for downsizing a substrate size in a semiconductor device.

A semiconductor device according to the present invention includes: a semiconductor substrate; and a semiconductor chip electrically connected to the semiconductor substrate via a plurality of terminals, wherein the semiconductor substrate includes an effective element area and a peripheral area surrounding the effective element area, the peripheral area is provided with an electrode portion to which the semiconductor chip is electrically connected, the semiconductor chip is provided with a plurality of rows of terminal groups disposed along a first direction, and W1>W2 is satisfied, where W1 is a distance from an end of the semiconductor chip on a side closest to the effective element area to the terminal group, and W2 is a distance from an end of the semiconductor chip on a side farthest from the effective element area to the terminal group.

Further features of the present invention will become apparent from the following description of exemplary embodiments with reference to the attached drawings.

### BRIEF DESCRIPTION OF THE DRAWINGS

FIG. 1 is a plan view schematically illustrating a conventional semiconductor device;

FIG. 2 is a plan view schematically illustrating a semiconductor device of a first embodiment;

FIG. 3A is a schematic diagram of the conventional semiconductor device;

FIG. 3B is a schematic diagram of the semiconductor device of the first embodiment;

FIG. 4 is a terminal arrangement diagram of the semiconductor chip according to a second embodiment;

FIG. 5A is a terminal arrangement diagram of the semiconductor chip according to a third embodiment, and FIG. 5B is a cross-sectional view thereof;

FIG. 6 is a schematic diagram illustrating a display device according to a fourth embodiment;

FIG. 7A is a schematic diagram illustrating an imaging apparatus according to the fourth embodiment;

FIG. 7B is a schematic diagram illustrating an electronic device according to the fourth embodiment;

FIGS. 8A and 8B are schematic diagrams illustrating display devices according to the fourth embodiment;

FIG. 9A is a schematic diagram illustrating an illumination device according to the fourth embodiment;

FIG. 9B is a schematic diagram illustrating a moving body according to the fourth embodiment; and

FIGS. 10A and 10B are schematic diagrams illustrating wearable devices according to the fourth embodiment.

### DESCRIPTION OF THE EMBODIMENTS

Embodiments of the present invention will be described with reference to the accompanying drawings. Note that, in the following description and drawings, common components are denoted by common reference numerals throughout the plurality of drawings. Therefore, common configurations will be described with reference to a plurality of drawings, and description of configurations denoted by common reference numerals will be appropriately omitted.

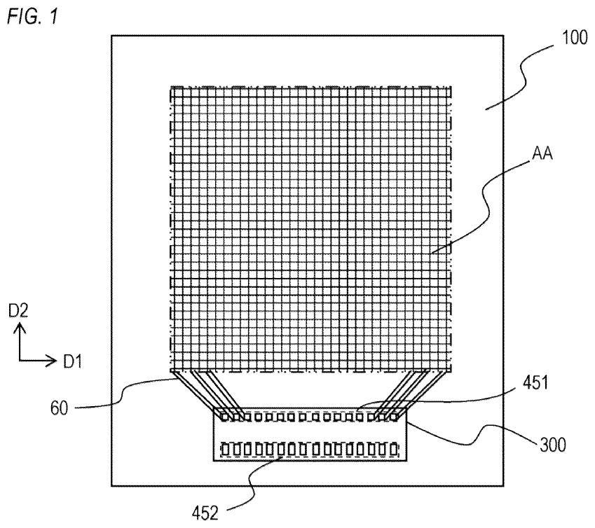

FIG. 1 is a plan view (schematic diagram) of a conventional semiconductor device in plan view. The arrangement in plan view is an arrangement when the semiconductor device is viewed from a direction perpendicular to the main surface of a semiconductor substrate 100 (normal direction of the main surface). The semiconductor substrate 100 includes an effective element area AA in which a functional element (not illustrated) is provided on a substrate such as silicon and a peripheral area located around the effective element area AA. In the peripheral area, an electrode portion (not illustrated) which is an external connection terminal is provided, and the electrode portion and the semiconductor chip 300 are electrically joined. The effective element area AA is electrically joined to the electrode portion by wiring 60. The semiconductor chip 300 is a semiconductor chip provided with a drive circuit, and terminal groups 451 and 452 in which a plurality of terminals are disposed along a longitudinal direction (direction D1 in FIG. 1: first direction) of the semiconductor chip are disposed on a surface connected to the semiconductor substrate 100.

Each of the terminal groups 451 and 452 constitutes an output terminal group or an input terminal group. For example, each terminal of the terminal group 451 can be an output terminal and each terminal of the terminal group 452 can be an input terminal, or each terminal of the terminal group 451 can be an input terminal and each terminal of the terminal group 452 can be an output terminal. A terminal group constituted by a pair of input terminals and output terminals arranged in the lateral direction (direction D2 in FIG. 1: second direction) of the semiconductor chip is referred to as an input/output terminal group. The input/output terminal group includes one or a plurality of input terminals and one or a plurality of output terminals. A plurality of rows of input/output terminal groups are disposed along the first direction of the semiconductor chip, and each of the input/output terminal groups is electrically connected to the semiconductor substrate as an external connection terminal (external connection terminal group).

In general, the number of output terminals is large, and a desired number of output terminals is disposed by reducing the size of the output terminals or increasing the number of rows of the output terminals in the lateral direction of the semiconductor chip. In general, when about 2,000 to 10,000 output terminals are disposed, the length of one side of the output terminal is about 10 μm to 100 μm, and the height of the output terminal is about 3 μm to 50 μm. The interval between the output terminals is about 10 μm to 100 μm, and the number of rows of the output terminals is about 3 to 20. The electrode portion (not illustrated) includes a plurality of electrodes to which a plurality of output terminals are connected via a connection member.

In general, the number of input terminals is smaller than the number of output terminals, and the input terminal is required to have low electrical resistance. Therefore, the size of the input terminal is preferably large. In general, when about 300 to 2,000 input terminals are disposed, the length of one side of the input terminal is about 10 μm to 200 μm, and the height of the input terminal is about 3 μm to 50 μm. The interval between the input terminals is about 10 μm to 50 μm, and the number of rows of the input terminals in the lateral direction of the semiconductor chip is about 1 to 5. The electrode portion includes a plurality of electrodes to which a plurality of input terminals are connected via a connection member.

A functional elements (not illustrated) can be provided in the effective element area AA of the semiconductor substrate 100. The functional element is a display element, a photoelectric conversion element, or the like. In the case of a display element, the functional element is an EL element in an electroluminescence display (ELD), a liquid crystal element in a liquid crystal display (LCD), or a reflective element in a digital mirror device (DMD).

The peripheral area may include a peripheral circuit area (not illustrated) in which a peripheral circuit is disposed. For example, in the case of a display device, the peripheral circuit includes a drive circuit for driving effective pixels, a processing circuit (for example, a digital-analog conversion circuit (DAC)) for processing signals input to the effective pixels, and the like. The peripheral area may include a non-effective element area (not illustrated) located outside the effective element area AA and provided with a non-effective element. The non-effective element is an element that does not function as an effective element, and is a dummy element, a reference element, a test element, a monitor element, or the like.

Both the electrode portion of the semiconductor substrate 100 and the terminal group of the semiconductor chip 300 are formed at a pitch facing each other. The electrode portion of the semiconductor substrate 100 is made of aluminum or the like disposed in an opening portion of a passivation layer, and each terminal of the semiconductor chip is a protruding bump formed of gold, copper, nickel, or the like. The bump can be formed by a method such as plating, vapor deposition, or stud bumps. The semiconductor substrate 100 and the semiconductor chip 300 can be connected by flip chip bonding or ultrasonic flip chip bonding.

The connection member between the semiconductor substrate 100 and the semiconductor chip 300 is ACF, NCF, epoxy resin, acrylic resin, solder, or the like. For example, the electrode of the semiconductor substrate 100 and the terminal of the semiconductor chip 300 are electrically connected by thermocompression bonding or ultrasonic compression bonding. ACF is a film in which conductive particles are dispersed in a thermosetting resin, and can be interpreted as an anisotropic conductive resin. As the thermosetting resin, an epoxy resin, an acrylic resin, or the like is used. The size and number of the conductive particles are selected according to the size of the terminal. For example, in a general ACF, the size (diameter) of the conductive particles is about 1 μm to 50 μm, and the number (area density) of the conductive particles is about 10,000˜100,000 particles/mm2. By using the NCF, the epoxy resin, or the acrylic resin, the connection strength and reliability between the electrode and the terminal can be improved.

### First Embodiment

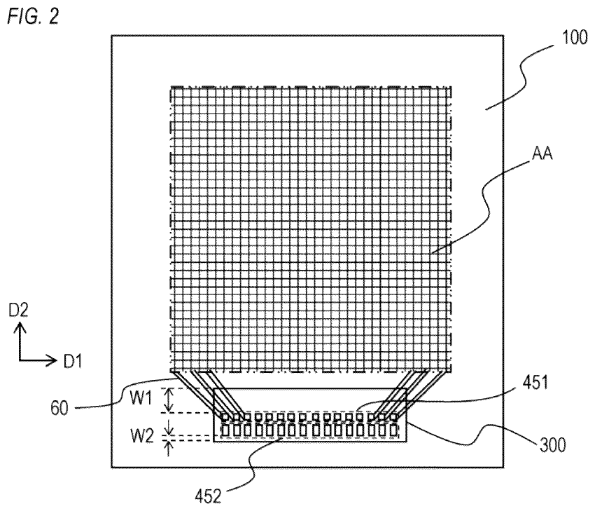

A first embodiment will be described. FIG. 2 is a plan view (schematic diagram) of a semiconductor device of the first embodiment in plan view. In the semiconductor device according to the first embodiment, the input/output terminal groups are disposed such that W1>W2. W1 is a (shortest) distance from an end of the semiconductor chip on the side closest to the effective element area AA of the semiconductor device to the input/output terminal groups. W2 is a (shortest) distance from an end of the semiconductor chip on the side farthest from the effective element area AA to the input/output terminal groups. In this manner, the interval between the terminal group 451 and the terminal group 452 is narrowed such that the terminal group 451 is disposed at a position away from the effective pixel area of the semiconductor substrate. In this way, an area without a terminal is formed in the semiconductor chip (on the effective element area AA side), and wiring (wiring between the effective element area and a wiring portion) in the area can be routed. As a result, a wiring routing area (area between the effective element area and the electrode portion) and the semiconductor chip can be overlapped, and the semiconductor chip can be brought close to the effective element area side, so that the semiconductor device itself can be downsized. In particular, in the case of a display device or an imaging apparatus, since the number of output terminals on the effective element side is large, the effect is large.

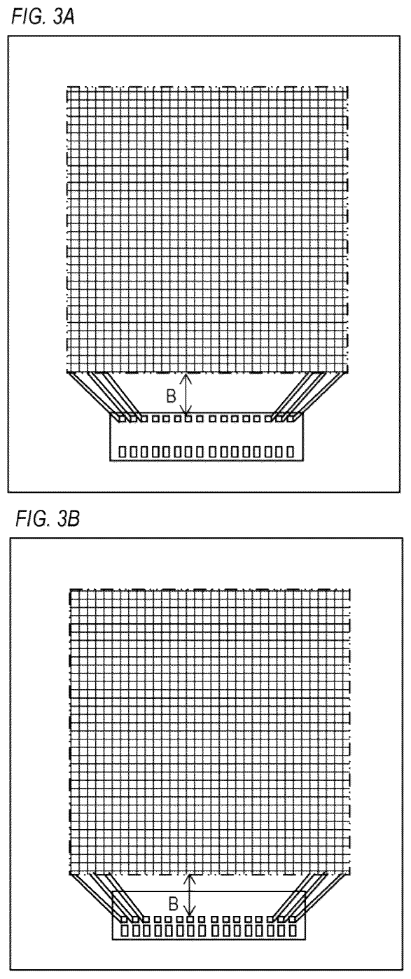

FIGS. 3A and 3B are diagrams for explaining a difference in size between the conventional semiconductor device and the semiconductor device of the first embodiment in relation to the arrangement of the input/output terminal group in the semiconductor device of the first embodiment. FIG. 3A is a schematic diagram of a conventional semiconductor device, and FIG. 3B is a schematic diagram of the semiconductor device of the first embodiment. A terminal group the side close to the effective element area AA is defined as an output terminal group (or input terminal group), and a distance from the effective element area AA to the output terminal group (or input terminal group) is defined as B. When the distance B is constant (the same wiring pattern), the semiconductor chip can be brought close to the effective element area side, so that the semiconductor substrate can be downsized as illustrated in FIG. 3B.

### Second Embodiment

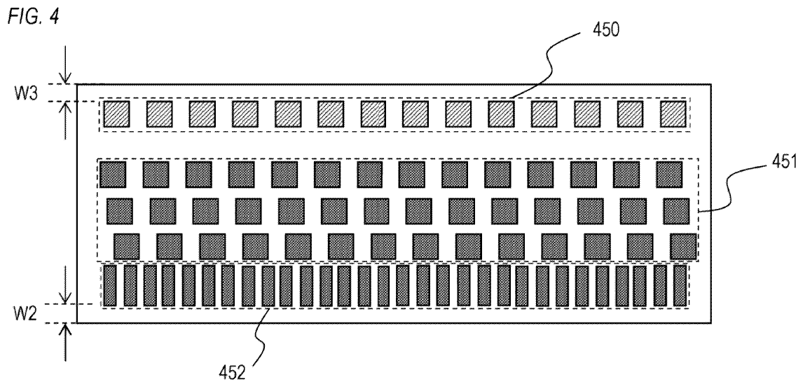

A second embodiment will be described. FIG. 4 is a plan view (schematic diagram) of the semiconductor chip according to the second embodiment in plan view. In the first embodiment, since the input/output terminal group of the semiconductor chip is disposed unevenly on one side, there is a possibility that the electrical connection becomes unstable when the semiconductor chip and the semiconductor substrate are connected. In the second embodiment, a dummy terminal group 450 is provided between the end of the semiconductor chip on the side closest to the effective element area AA of the semiconductor device and the input/output terminal group. As a result, the load applied between the electrode portion and the terminal group at the time of joining can be equalized, and the electrical connection can be stabilized.

Furthermore, in the second embodiment, when the distance from the end of the semiconductor chip on the side closest to the effective element area AA of the semiconductor device to the dummy terminal group 450 is W3, the dummy terminal group 450 is disposed such that W2=W3. As a result, the uniformity of the terminal arrangement of the semiconductor chip is further improved, and the electrical connection can be further stabilized. According to the second embodiment, it is possible to obtain the effect of equalizing the load applied between the electrode portion and the terminal group at the time of joining, and it is possible to downsize the semiconductor device and stabilize the electrical connection.

### Third Embodiment

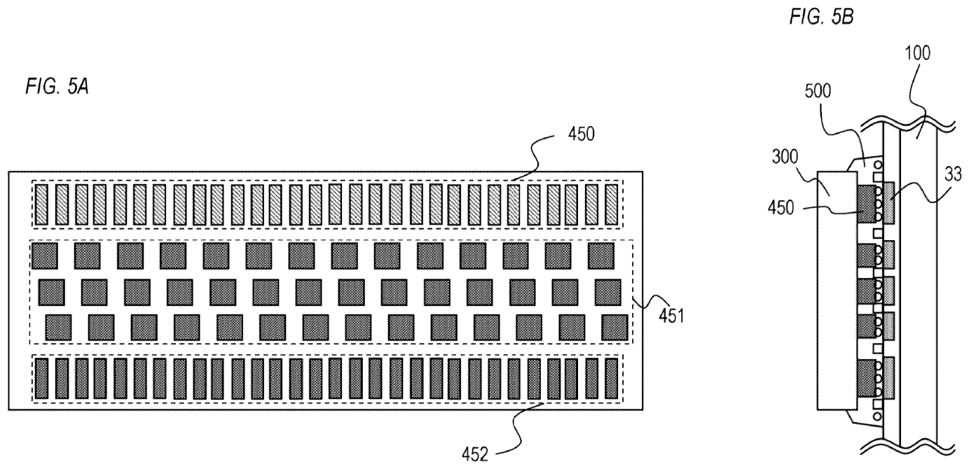

A third embodiment will be described. FIG. 5A is a terminal arrangement diagram of the semiconductor chip according to the third embodiment. In the second embodiment, a dummy terminal group is provided between the end of the semiconductor chip on the side closest to the effective element area AA and the output terminals (or input terminals) 451. In the third embodiment, the shape of each terminal and the number of terminals in the dummy terminal group are made the same as the shape of each terminal and the number of terminals in the terminal group 452 on the side farthest from the effective element area. As a result, a load can be more uniformly applied, and connection stability can be achieved. According to the third embodiment, it is possible to obtain the effect of equalizing the load applied between the electrode portion and the terminal group at the time of joining, and it is possible to downsize the semiconductor device and stabilize the electrical connection.

FIG. 5B is a cross-sectional view of a joining portion between the semiconductor chip and the semiconductor substrate according to the third embodiment. The semiconductor chip 300 is electrically connected to an electrode portion 33 of the semiconductor substrate 100 via a connection member 500. For the connection member 500, a conductive member such as an anisotropic conductive adhesive film (ACF), a non-conductive adhesive film (NCF), an epoxy resin, an acrylic resin, and the like is used. The semiconductor substrate 100 is made of a semiconductor such as single crystal silicon.

As described above, by using the semiconductor device according to the first to third embodiments, the semiconductor device can be downsized.

### Fourth Embodiment

In the fourth embodiment, an example in which the semiconductor device according to the first to third embodiments is applied to various devices will be described. In a case where the semiconductor device is used in a display device, the semiconductor substrate 100 is a display element substrate, and a light emitting element is disposed in the effective element area AA. Furthermore, in a case where the semiconductor device is used in an imaging apparatus, the semiconductor substrate 100 is an imaging element substrate, and an imaging element is disposed in the effective element area AA.

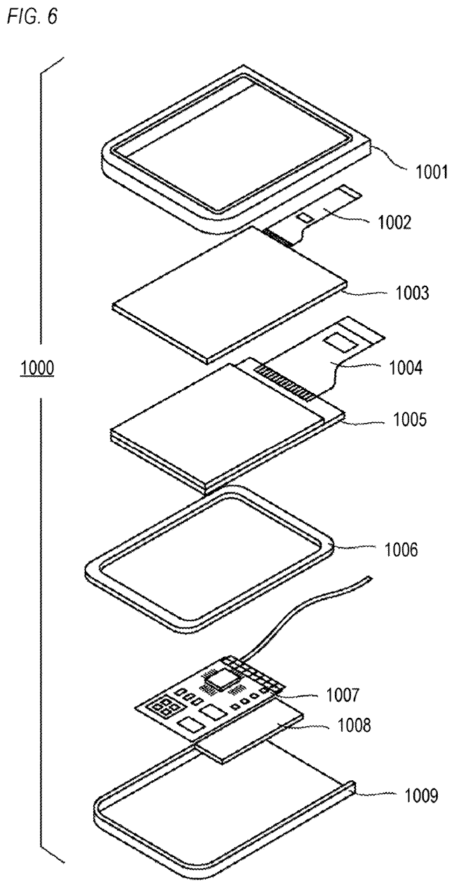

FIG. 6 is a schematic diagram illustrating a display device 1000 which is an example of a display device according to the fourth embodiment. The display device 1000 may include a touch panel 1003, a display panel 1005, a frame 1006, a circuit board 1007, and a battery 1008 between an upper cover 1001 and a lower cover 1009.

The display panel 1005 is a display unit including the semiconductor device according to the first to third embodiments, and performs display using light emitted from the semiconductor device. Flexible printed circuits FPCs 1002 and 1004 are connected to the touch panel 1003 and the display panel 1005. A control circuit including a transistor is printed on the circuit board 1007, and performs various controls such as control of the display panel 1005. The battery 1008 may not be provided unless the display device is a portable device, or may be provided at another position even if the display device is a portable device. The display device 1000 may include three types of color filters corresponding to red, green, and blue, respectively. The plurality of color filters may be disposed in a delta array.

The display device 1000 may be used for a display unit of a mobile terminal. At that time, the display device 1000 may have both a display function and an operation function. Examples of the mobile terminal include a mobile phone such as a smartphone, a tablet, and a head-mounted display.

The display device 1000 may be used for a display unit of an imaging apparatus including an optical unit having a plurality of lenses and an imaging element that receives light passing through the optical unit. The imaging apparatus may include a display unit that displays information (such as an image captured by the imaging element) acquired by the imaging element. Furthermore, the display unit may be a display unit exposed to the outside of the imaging apparatus or a display unit disposed in a finder. The imaging apparatus may be a digital camera, a digital video camera, and the like.

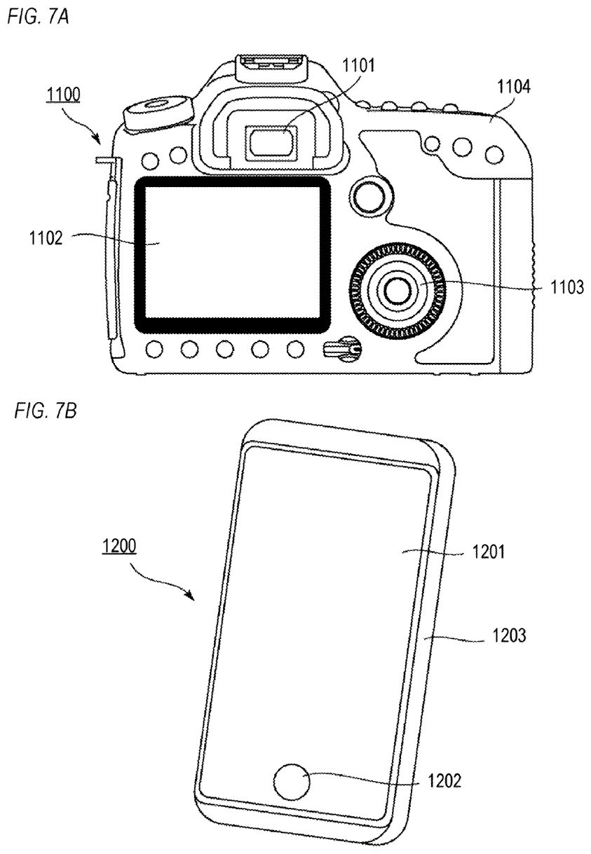

FIG. 7A is a schematic diagram illustrating an imaging apparatus 1100 which is an example of an imaging apparatus according to a fourth embodiment. The imaging apparatus 1100 may include a view finder 1101, a rear display 1102, an operation unit 1103, and a housing 1104. The view finder 1101 may include the display device (display device including the semiconductor device according to the first to third embodiments and performing display using light emitted from the semiconductor device) according to the fourth embodiment. In this case, the display device may display not only an image to be captured but also environmental information, an imaging instruction, and the like. The environmental information may be intensity of external light, a direction of the external light, a moving speed of a subject, a possibility that the subject is shielded by a shielding object, and the like. The rear display 1102 may also include the display device according to the fourth embodiment.

Since the timing suitable for imaging is a short time, it is better to display the information as soon as possible. Therefore, it is preferable to use a display device using an organic light emitting element having a high response speed. The display device using the organic light emitting element can be suitably used in a device requiring a display speed as compared with a liquid crystal display device or the like.

The imaging apparatus 1100 includes an optical unit (not illustrated). The optical unit includes a plurality of lenses and forms an image of light on an imaging element housed in the housing 1104. The plurality of lenses can adjust the focal point by adjusting their relative positions. This operation can also be performed automatically. The imaging apparatus 1100 may be referred to as a photoelectric conversion device. The photoelectric conversion device may include, as an imaging method, a method of detecting a difference from a previous image, a method of cutting out a part of a recorded image, and the like, instead of sequentially imaging.

FIG. 7B is a schematic diagram illustrating an electronic device 1200 which is an example of an electronic device according to the fourth embodiment. The electronic device 1200 includes a display unit 1201, an operation unit 1202, and a housing 1203. The display unit 1201 includes the semiconductor device according to the first to third embodiments, and performs display using light emitted from the semiconductor device. The electronic device 1200 may include, in the housing 1203, a circuit, a printed circuit board including the circuit, a battery, and a communication unit that communicates with the outside. The operation unit 1202 may be a button or a touch panel type reaction unit. The operation unit may be a biological recognition unit that recognizes a fingerprint and releases a lock or the like. The electronic device having the communication unit can also be referred to as a communication device. The electronic device may further include a camera function by including a lens and an imaging element. An image captured by the camera function is displayed on the display unit. Examples of the electronic device include a smartphone and a notebook computer.

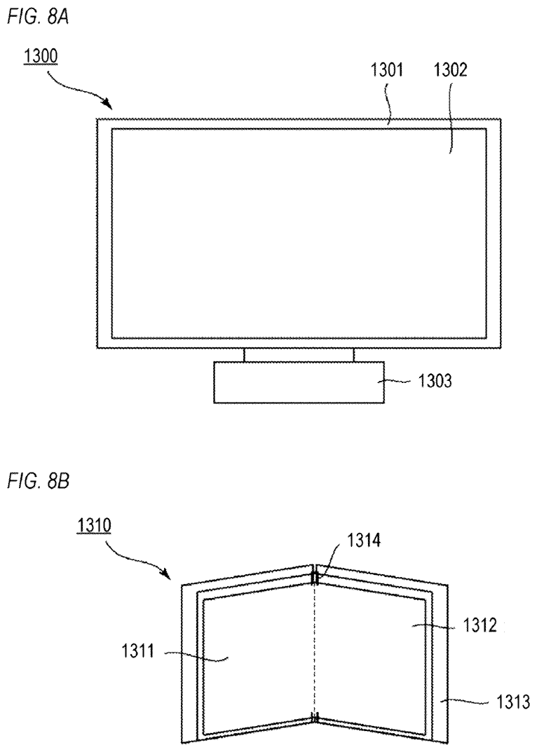

FIG. 8A is a schematic diagram illustrating a display device 1300 which is an example of the display device according to the fourth embodiment. The display device 1300 is a display device such as a television monitor or a PC monitor. The display device 1300 includes a frame 1301, a display unit 1302, and a base 1303 that supports the frame 1301 and the display unit 1302. The display unit 1302 includes the semiconductor device according to the first to third embodiments, and performs display using light emitted from the semiconductor device. The form of the base 1303 is not limited to the form of FIG. 8A. The lower side of the frame 1301 may also serve as the base 1303. The frame 1301 and the display unit 1302 may be bent. The radius of curvature may be 5000 mm or more and 6000 mm or less.

FIG. 8B is a schematic diagram illustrating a display device 1310 which is an example of the display device according to the fourth embodiment. The display device 1310 is a so-called foldable display device configured to be bendable. The display device 1310 includes a first display unit 1311, a second display unit 1312, a housing 1313, and a bending point 1314. Each of the first display unit 1311 and the second display unit 1312 includes the semiconductor device according to the first to third embodiments, and performs display using light emitted from the semiconductor device. The first display unit 1311 and the second display unit 1312 may be one display device without a joint. The first display unit 1311 and the second display unit 1312 can be divided at the bending point. The first display unit 1311 and the second display unit 1312 may display different images, or the first display unit 1311 and the second display unit 1312 may display one image.

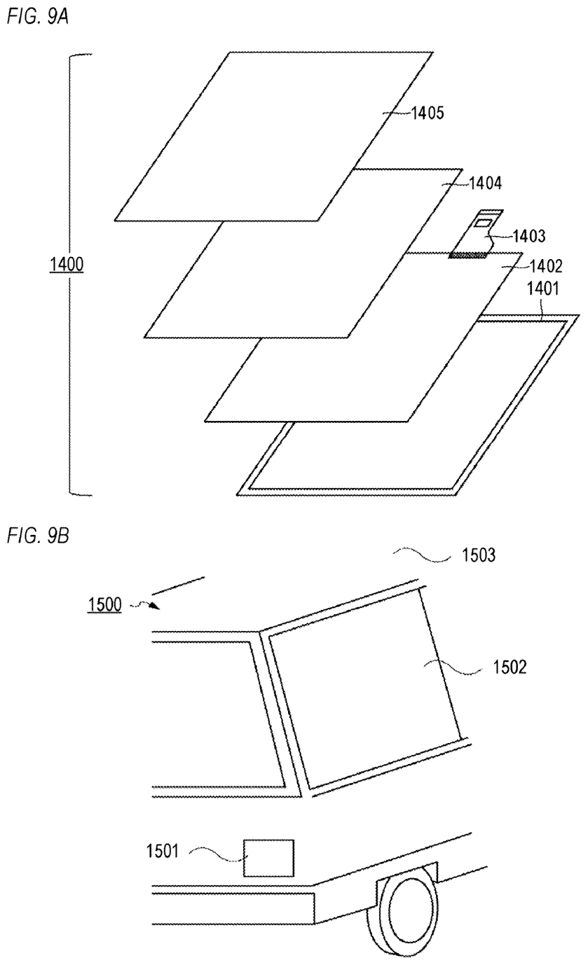

FIG. 9A is a schematic diagram illustrating an illumination device 1400 which is an example of an illumination device according to the fourth embodiment. The illumination device 1400 may include a housing 1401, a light source 1402, a circuit board 1403, an optical film 1404, and a light diffusion portion 1405. The light source 1402 includes the semiconductor device according to the first to third embodiments. The optical film 1404 may be a filter (optical filter) that improves the color rendering properties of the light source 1402. The light diffusion portion 1405 can effectively diffuse the light of the light source 1402 such as light up and deliver the light to a wide range. The optical film 1404 and the light diffusion portion 1405 may be provided on the light emission side of the illumination device 1400. If necessary, a cover may be provided on the outermost part.

The illumination device 1400 is, for example, a device that illuminates the interior. The illumination device 1400 may emit white light, neutral white light, and other colors (any color from blue to red). White is a color having a color temperature of 4200 K, and neutral white is a color having a color temperature of 5000 K. The illumination device 1400 may include a light control circuit that controls a light emission color of the illumination device 1400. The illumination device 1400 may include a power supply circuit connected to the light source 1402. The power supply circuit is a circuit that converts an AC voltage into a DC voltage. In addition, the illumination device 1400 may include a color filter. In addition, the illumination device 1400 may include a heat dissipation portion. The heat dissipation portion releases heat in the device to the outside of the device, and examples thereof include a metal having high specific heat and liquid silicon.

FIG. 9B is a schematic diagram illustrating an automobile 1500 which is an example of a moving body according to the fourth embodiment. The automobile 1500 may include a tail lamp 1501 which is an example of a lamp. The tail lamp 1501 is turned on in response to a brake operation or the like.

The tail lamp 1501 includes the semiconductor device according to the first to third embodiments. The tail lamp 1501 may include a protection member that protects the semiconductor device. The protection member has high strength to some extent, and is preferably made of polycarbonate or the like although the material is not limited as long as it is transparent. A furandicarboxylic acid derivative, an acrylonitrile derivative, or the like may be mixed with polycarbonate.

The automobile 1500 may have a vehicle body 1503 and a window 1502 attached to the vehicle body 1503. The window 1502 may be a transparent display as long as it is not a window for checking the front and rear of the automobile 1500. The transparent display may include the semiconductor device according to the first to third embodiments. In this case, a constituent material such as an electrode included in the semiconductor device is formed of a transparent member.

The moving body according to the fourth embodiment may be a ship, an aircraft, a drone, or the like. The moving body may include a machine body and a lamp provided on the machine body. The lamp may emit light for notifying the position of the machine body. The lamp includes the semiconductor device according to the first to third embodiments.

The display device (display device including the semiconductor device according to the first to third embodiments and performing display using light emitted from the semiconductor device) according to the fourth embodiment can also be applied to wearable devices such as smart glasses, HMDs, and smart contacts. The display device according to the fourth embodiment can also be applied to a system including a wearable device or the like. An imaging display device used as a wearable device or the like includes an imaging apparatus capable of photoelectrically converting visible light and a display device capable of emitting visible light.

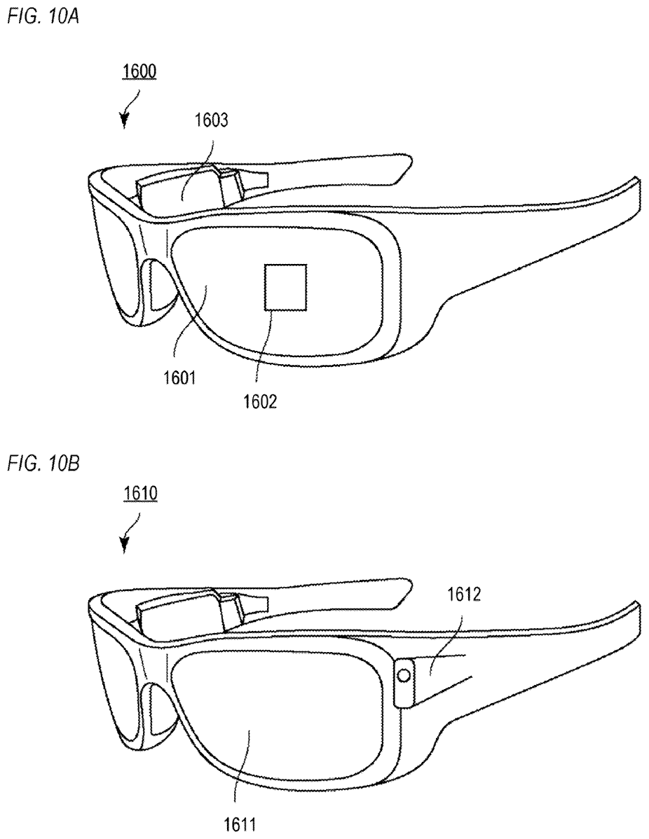

FIG. 10A is a schematic diagram illustrating glasses 1600 (smart glasses) as an example of a wearable device according to the fourth embodiment. An imaging apparatus 1602 such as a CMOS sensor or a SPAD is provided on the front surface side of a lens 1601 of the glasses 1600. The display device (display device including the semiconductor device according to the first to third embodiments and performing display using light emitted from the semiconductor device) according to the fourth embodiment is provided on the back surface side of the lens 1601.

The glasses 1600 further includes a control device 1603. The control device 1603 functions as a power supply that supplies power to the imaging apparatus 1602 and the display device. Furthermore, the control device 1603 controls operations of the imaging apparatus 1602 and the display device. The lens 1601 is formed with an optical system for condensing light on the imaging apparatus 1602.

FIG. 10B is a schematic diagram illustrating glasses 1610 (smart glasses) as an example of the wearable device according to the fourth embodiment. The glasses 1610 include a control device 1612, and an imaging apparatus corresponding to the imaging apparatus 1602 and the display device according to the fourth embodiment are mounted on the control device 1612. A lens 1611 is formed with the imaging apparatus in the control device 1612 and an optical system for projecting light emitted from the display device, and an image is projected on the lens 1611. The control device 1612 functions as a power supply that supplies power to the imaging apparatus and the display device, and controls operations of the imaging apparatus and the display device.

The control device may include a line-of-sight detector that detects the line of sight of a wearer of the glasses 1610. A line of sight may be detected using infrared light. An infrared light emitting unit emits infrared light to an eyeball of the user gazing at a display image. A captured image of the eyeball is obtained by an imaging unit including a light receiving element detecting reflected light from the eyeball of the emitted infrared light. By including a reduction unit that reduces light from the infrared light emitting unit to a display unit in plan view, deterioration in quality of an image projected from the display device onto the lens 1611 is reduced. The control device detects the line of sight of the user with respect to the display image from the captured image of the eyeball obtained by the imaging of the infrared light. Any known method can be applied to the line-of-sight detection using the captured image of the eyeball. As an example, a line-of-sight detection method based on a Purkinje image by reflection of irradiation light at the cornea can be used. More specifically, line-of-sight detection processing based on the pupillary and corneal reflex method is performed. A line-of-sight vector indicating the direction (rotation angle) of the eyeball is calculated based on the image of the pupil and the Purkinje image included in the captured image of the eyeball using the pupillary and corneal reflex method, whereby the line of sight of the user is detected.

Note that, in a case where display control is performed on the basis of visual recognition detection (line-of-sight detection), the semiconductor device according to the first to third embodiments can be preferably applied to smart glasses having an imaging apparatus that images the outside. The smart glasses can display the imaged external information in real time.

Note that the display device (display device including the semiconductor device according to the first to third embodiments and performing display using light emitted from the semiconductor device) according to the fourth embodiment may include an imaging apparatus having a light receiving element, and may control a display image on the basis of the line-of-sight information of a user from the imaging apparatus. Specifically, a first field-of-view area at which the user gazes and a second field-of-view area other than the first field-of-view area are determined on the basis of the line-of-sight information. The first field-of-view area and the second field-of-view area may be determined by the control device of the display device, or may be determined by an external control device and received by the display device. In a display area of the display device, the display resolution of the first field-of-view area may be controlled to be higher than the display resolution of the second field-of-view area. That is, the resolution of the second field-of-view area may be lower than that of the first field-of-view area.

In addition, the display area may have a first display area and a second display area different from the first display area, and an area having a high priority may be determined from the first display area and the second display area on the basis of the line-of-sight information. The first display area and the second display area may be determined by the control device of the display device, or may be determined by an external control device and received by the display device. The resolution of an area with high priority may be controlled to be higher than the resolution of an area other than the area with high priority. That is, the resolution of an area having a relatively low priority may be lowered.

Note that AI may be used to determine the first field-of-view area, the area with high priority, and the like. The AI may be a model configured to estimate the angle of a line of sight and the distance to a target object ahead of the line of sight from an image of an eyeball using an image of the eyeball and the direction actually viewed by the eyeball in the image as teacher data. An AI program may be included in the display device, the imaging apparatus, or an external device. In a case where the external device has the AI program, the determination is transmitted to the display device via communication.

As described above, by using the semiconductor device according to the first to third embodiments, various devices can perform stable display for a long time with favorable image quality.

Note that the functional units (configurations) of the various devices described in the fourth embodiment may or may not be individual hardware. The functions of two or more functional units may be implemented by common hardware. Each of a plurality of functions of one functional unit may be implemented by individual hardware. Two or more functions of one functional unit may be implemented by common hardware. In addition, each functional unit may or may not be implemented by hardware such as ASIC, FPGA, and DSP. For example, the device may include a processor and a memory (storage medium) storing a control program. Then, the functions of at least some functional units included in the device may be implemented by the processor reading and executing the control program from the memory.

According to the present invention, it is possible to provide a technique advantageous for downsizing a semiconductor device. By disposing the terminal of the semiconductor chip at a position away from the effective element area of the semiconductor substrate, wiring on the substrate side can be routed in an area without the terminal. Therefore, since the wiring routing area (area between the effective element area and the electrode portion) and the semiconductor chip can be overlapped, the semiconductor device itself can be downsized. In particular, in the case of a display device or an imaging apparatus, since the number of output terminals on the effective pixel side is large, the effect is large.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-215504, filed on Dec. 21, 2023, which is hereby incorporated by reference herein in its entirety.

What is claimed is:

1. A semiconductor device comprising:
a semiconductor substrate; and
a semiconductor chip electrically connected to the semiconductor substrate via a plurality of terminals, wherein
the semiconductor substrate includes an effective element area and a peripheral area surrounding the effective element area,
the peripheral area is provided with an electrode portion to which the semiconductor chip is electrically connected,
the semiconductor chip is provided with a plurality of rows of terminal groups disposed along a first direction, and
W1>W2 is satisfied, where
W1 is a distance from an end of the semiconductor chip on a side closest to the effective element area to the terminal group, and
W2 is a distance from an end of the semiconductor chip on a side farthest from the effective element area to the terminal group.

2. The semiconductor device according to claim 1, wherein
a dummy terminal group is disposed between the end of the semiconductor chip on the side closest to the effective element area of the semiconductor substrate and the terminal group.

3. The semiconductor device according to claim 2, wherein
a dummy terminal is disposed such that W2=W3 is satisfied, where
W3 is a distance from the end of the semiconductor chip on the side closest to the effective element area of the semiconductor substrate to the dummy terminal group.

4. The semiconductor device according to claim 2, wherein
a shape of each terminal and number of terminals in the dummy terminal group are a same as a shape of each terminal and number of terminals in the terminal group on the side farthest from the effective element area of the semiconductor substrate.

5. The semiconductor device according to claim 1, wherein the semiconductor chip is electrically connected to the semiconductor substrate by flip chip bonding.

6. The semiconductor device according to claim 1, wherein
the semiconductor chip is electrically connected to the semiconductor substrate using an anisotropic conductive film.

7. The semiconductor device according to claim 1, wherein
the semiconductor chip is electrically connected to the semiconductor substrate by ultrasonic flip chip bonding.

8. The semiconductor device according to claim 1, wherein
the semiconductor chip is electrically connected to the semiconductor substrate by solder.

9. The semiconductor device according to claim 1, wherein
the terminal group includes input terminals or output terminals.

10. The semiconductor device according to claim 1, wherein
the terminal group includes input terminals and output terminals.

11. A display device comprising:
a display including the semiconductor device according to claim 1; and
a control circuit configured to control the display.

12. A photoelectric conversion device comprising:
an optical member;
an imaging element configured to receive light that has passed through the optical member; and
a display configured to display an image captured by the imaging element, wherein
the display includes the semiconductor device according to claim 1.

13. An electronic device comprising:
a display including the semiconductor device according to claim 1;
a housing in which the display is provided; and
a communication interface that is provided in the housing and communicates with an outside.
